(19) United States
(12) Patent Application Publication
(10) Pub. No.: US 2010/0123126 A1
(43) Pub. Date: May 20, 2010

(54) ORGANIC ELECTROLUMINESCENT ELEMENT

(75) Inventor: Yoshitaka KITAMURA, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/617,736

(22) Filed: Nov. 13, 2009

(30) Foreign Application Priority Data
Nov. 20, 2008 (JP) 2008-296859

(51) Int. Cl. H01L 51/52

(52) U.S. Cl. 257/40; 257/E51.018

(57) ABSTRACT

An organic electroluminescent element 10 includes a first electrode 14, an organic layer 16 including at least a light emitting layer, and a second electrode 20, disposed in this order, in which the second electrode includes, starting from the organic layer side, an Al layer 18 having a thickness of 0.1 nm to 10 nm and an Ag layer 19 having a thickness of 3 nm to 50 nm. Preferably, the organic layer includes an electron injection layer doped with an alkali metal, and a layer of an alloy of Al and Li is disposed between the organic layer and the second electrode.

### CROSS REFERENCE TO RELATED APPLICATION

This application claims priority under 35USC 119 from Japanese Patent Application No. 2008-296859 filed on Nov. 20, 2008, the disclosure of which is incorporated herein by reference.

### BACKGROUND OF THE INVENTION

1. Field of the Invention

The present invention relates to an organic electroluminescent element.

2. Description of the Related Art

In recent years, light emitting devices or display devices using organic electroluminescent elements have been proposed. An organic electroluminescent element includes a pair of electrodes (an anode and a cathode) facing each other and an organic layer containing a light emitting material that is interposed between the electrodes, and when a voltage is applied between the electrodes, holes and electrons in the organic layer (light emitting layer) of the region interposed between the electrodes recombine to emit light.

The material constituting the electrodes may be a metal such as gold, silver, aluminum, chromium or nickel; an electroconductive metal oxide such as tin oxide doped with antimony or fluorine (ATO or FTO), tin oxide, zinc oxide, indium oxide, indium tin oxide (ITO), or indium zinc oxide (IZO); an inorganic electroconductive substance such as copper iodide or copper sulfide; or an organic electroconductive material such as polyaniline, polythiophene or polypyrrole.

The electrodes are selected by taking account of electrical conductivity, light transparency, light reflectivity, film formability and the like, but it is necessary that an electrode having light transparency is formed at least at the side of extracting the light from the light emitting layer.

It has also been suggested to construct an electrode by forming films through deposition or the like using the materials having electrical conductivity, and to produce an electrode composed of plural layers, without restricting to a single layer. For example, an organic electroluminescent element provided with a protective electrode containing any one or more of aluminum (Al), titanium (Ti), a transition metal other than Al and Ti, and titanium nitride, on a cathode formed of an aluminum-lithium (AlLi) alloy has been proposed (see Japanese Patent Application Laid-Open (JP-A) No. 10-321374).

An organic electroluminescent element having, as a cathode, a transparent calcium (Ca) layer (electron injection layer) and a transparent silver (Ag) layer (coating layer) formed on an organic layer has also been proposed (see JP-A No. 2004-200141).

### SUMMARY OF THE INVENTION

The present invention has been made in view of the above circumstances, and provides the following organic electroluminescent element.

According to an aspect of the invention, an organic electroluminescent element including a first electrode, an organic layer including at least a light emitting layer, and a second electrode, disposed in this order, in which the second electrode includes, starting from the side of the organic layer, an Al layer having a thickness of 0.1 nm to 10 nm and an Ag layer having a thickness of 3 nm to 50 nm is provided.

### BRIEF DESCRIPTION OF THE DRAWINGS

FIG. 1 is a schematic structural view showing a device equipped with the organic electroluminescent element according to an exemplary embodiment of the present invention;

FIGS. 2A, 2B, 2C and 2D are diagrams showing the constitution of the layers above the electron transport layer in the Example; and

FIGS. 3A, 3B and 3C are diagrams showing the constitution of the layers above the electron transport layer in the Comparative Example.

### DETAILED DESCRIPTION OF THE INVENTION

Hereinafter, the organic electroluminescent element according to the present invention will be described by making reference to the attached drawings.

In the case of producing an organic electroluminescent element of so-called top emission type, in which the light emitted from the light emitting layer is extracted through the side opposite to the supporting substrate, that is, through the side of the electrode (upper electrode) above the organic layer, the upper electrode needs to be transparent to the light emitted from the light emitting layer. Furthermore, in the case of extracting light from both surfaces, it is necessary to form the upper and lower electrodes to have light transparency.

When producing a top emission organic electroluminescent element having a so-called resonator structure, in which a light with a specific wavelength emitted from the light emitting layer is made to resonate by reflecting repeatedly between the upper and lower electrodes so as to enhance the luminance or to enhance the color purity, it is necessary to form the lower electrode so as to have reflectivity, and to form the upper electrode so as to have reflectivity as well as transparency, with respect to the light emitting from the light emitting layer. When such an organic electroluminescent element having a resonator structure is to be formed, it is generally preferable to form an Ag electrode as the electrode on the organic layer, from the viewpoint of obtaining a balance between the electrical conductivity required of an electrode and the light reflectivity. For example, if an Al electrode having light reflectivity and an organic layer including a light emitting layer are sequentially formed on a substrate, and then an Ag electrode is formed on the organic layer to a thickness exhibiting reflectivity and transparency with respect to the light emitted from the light emitting layer, a top emission type organic electroluminescent element having a resonator structure can be obtained.

However, it is found as a result of the investigation conducted by the inventor of the invention, that an Ag electrode formed on an organic layer is prone to causing short circuits. Although the cause is still not clearly known, it is speculated that upon forming an Ag layer by deposition, Ag easily penetrates deeply into the organic layer, and this serves as a factor of short circuiting.

Thus, the inventor of the invention has conducted extensive research and, as a result, it was found that an organic electroluminescent element that suppresses the occurrence of short circuits, has high electron injectability into the organic layer, and is driven at a low voltage, while suppressing any voltage increase resulting from the use of the element, may be obtained by sequentially forming an Al layer and an Ag layer, which are both highly stable, to their respective specific thicknesses, as a second electrode (cathode) on an organic layer.

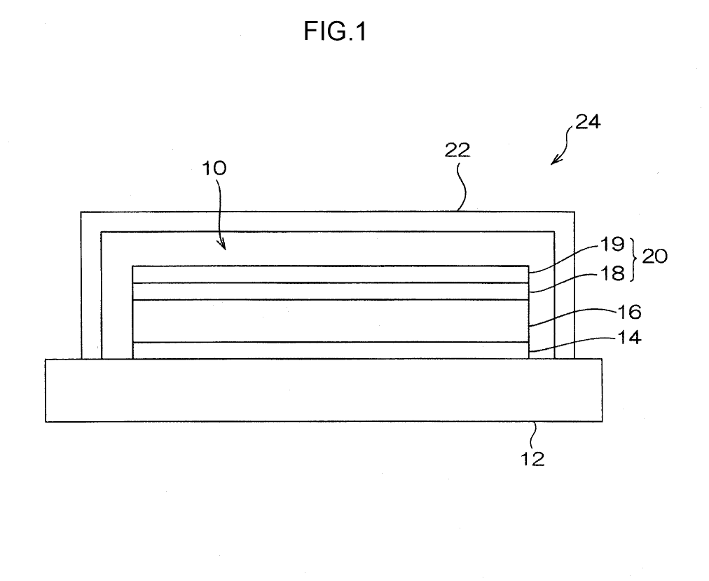

FIG. 1 schematically shows the configuration of a light emitting device equipped with the organic electroluminescent element according to an exemplary embodiment of the invention. The organic electroluminescent element 10 of the exemplary embodiment is constituted of a first electrode 14, an organic layer 16 including at least a light emitting layer, and a second electrode 20 formed on a support 12 in this order, and is a so-called top emission type element in which the light emitted from the light emitting layer passes through the second electrode 20 and is extracted. The second electrode 20 is constituted of an Al layer 18 and an Ag layer 19 disposed from the side of the organic layer 16, and the thickness of the Al layer 18 is from 0.1 nm to 10 nm, while the thickness of the Ag layer 19 is from 3 nm to 50 nm.

Hereinafter, various components of the configuration will be specifically described.

<Support>

The substrate (support) 12 on which the organic electroluminescent element 10 is formed, is not particularly limited as long as it has a strength sufficient to support the organic electroluminescent element 10, and any known substrate may be used. Examples of the material of the substrate include inorganic materials such as yttria-stabilized zirconia (YSZ), and glass; and organic materials such as, polyester such as polyethylene terephthalate, polybutylene phthalate, polyethylene naphthalate and the like, polystyrene, polycarbonate, polyethersulfone, polyarylate, polyimide, polycycloolefin, norbornene resin, and poly(chlorotrifluoroethylene).

When a substrate made of glass is used as the supporting substrate 12, the glass is preferably non-alkali glass in order to decrease ions eluted from the glass. When soda lime glass is used, it is preferred to provide a barrier coat such as silica on the glass.

In the case of using the supporting substrate 12 made of an organic material, it is preferred that the substrate 12 is excellent in heat resistance, dimension stability, solvent resistance, electrical insulation and workability. In the case of using, in particular, a plastic supporting substrate 12, it is preferred to form a moisture permeation preventing layer or a gas barrier layer onto one side or both sides of the supporting substrate 12 in order to restrain the permeation of moisture or oxygen. The material of the moisture permeation preventing layer or the gas barrier layer is preferably an inorganic material such as silicon nitride, silicon oxide, silicon oxynitride, or aluminum oxide, or a laminate composed of two or more selected from the inorganic materials and organic materials such as acrylic resin. The moisture permeation preventing layer or the gas barrier layer may be formed by, for example, high-frequency sputtering.

In the case of using a thermoplastic supporting substrate, a hard coat layer, an undercoat layer or the like may be formed thereon as the need arises.

The shape, the structure, the size and other characters of the supporting substrate 12 are not particularly limited, and these may be appropriately selected in accordance with the use manner and the use purpose of the organic electroluminescent element 10. In general, the shape of the supporting substrate 12 is preferably a plate-like shape from the viewpoint of the handleability and the easiness of formation of the organic electroluminescent element. The structure of the supporting substrate may be a monolayer structure or a layered structure. The supporting substrate 12 may be made of a single member, or two or more members.

In the case of a top emission-type device in which light is extracted from the side of the second electrode 20, it is not necessary to extract light from the side of the supporting substrate 12, and thus the supporting substrate may be a metal substrate of stainless steel, Fe, Al, Ni, Co, Cu or an alloy thereof, or a silicon substrate. The supporting substrate made of a metal has high strength and high gas barrier properties against moisture and oxygen in the air, even if the substrate is thin. When the metallic supporting substrate is used, an insulating film for securing electrical insulation properties may be disposed between the supporting substrate 12 and the first electrode 14.

<First Electrode>

The first electrode 14 formed on the supporting substrate 12 is not particularly limited about the shape, the structure, the size and other characters as long as the electrode is a member having a function of an electrode (anode) for supplying holes to the organic layer 16. The electrode may be appropriately selected from known electrode materials in accordance with the use manner and the use purpose of the organic electroluminescent element.

Preferred examples of the material which constitutes the first electrode 14 include metals, alloys, metal oxides, electroconductive compounds, and mixtures thereof. Specific examples thereof include electroconductive metal oxides such as tin oxide doped with antimony or fluorine (ATO, or FTO), tin oxide, zinc oxide, indium oxide, indium tin oxide (ITO), and indium zinc oxide (IZO); metals such as gold, silver, aluminum, chromium, and nickel; mixtures or laminates each composed of two or more selected from the metals and the electroconductive metal oxides; electroconductive inorganic materials such as copper iodide and copper sulfide; electroconductive organic materials such as polyaniline, polythiophene, and polypyrrole; and laminates each composed of one or more selected from these materials, and ITO.

For example, in the case of producing an organic electroluminescent element having a resonator structure by allowing the light emitted from the light emitting layer to reflect between the two electrodes 14 and 20, the first electrode 14 may be formed such that a material having light reflectivity forms the uppermost surface. As the material having light reflectivity, specifically, an Al electrode and an Ag electrode are preferable.

On the other hand, in the case of producing an organic electroluminescent element with double-sided light emission, which emits light from both of the electrodes 14 and 20, the light transparency of the first electrode 14 is preferably 60% or higher, and more preferably 70% or higher. Specifically, ITO is preferable for the first electrode. Transparent electrodes are described in detail in “Development of Transparent Conductive Films”, supervised by Yutaka Sawada, published by CMC Publishing Co., Ltd. (1999). Matters described therein may be applied to the invention. In the case of using, for example, a low heat-resistant supporting substrate made of a plastic, ITO or IZO is used. A transparent electrode made into a film form at a low temperature of 150° C. or lower is preferred.

Examples of the method for forming the first electrode 14 include wet methods such as printing and coating methods; physical methods such as vacuum deposition, sputtering, and ion plating; and chemical methods such as CVD and plasma CVD. The method may be appropriately selected, considering suitability for the material which constitutes the first electrode 14. When ITO is used as the first electrode, for example, the first electrode 14 may be formed on the supporting substrate 12 by direct current or high frequency sputtering, vacuum deposition, ion plating or the like.

The position in which the first electrode 14 is to be formed can be selected appropriately depending on the use, object etc. of the emitting device 24. The first electrode 14 may be formed wholly or partially on the supporting substrate 12.

When the first electrode 14 is formed, patterning may be performed by chemical etching based on photolithography or the like, or by physical etching using a laser or the like. The patterning may be performed by vacuum vapor deposition, sputtering or the like via a mask superimposed on the substrate. The patterning may be performed by a liftoff method or a printing method.

The thickness of the first electrode 14 may be appropriately selected in accordance with the material which constitutes the first electrode 14, and is usually from about 10 nm to 50 um, preferably from 50 nm to 20 μm.

The resistivity of the first electrode 14 is preferably from 10³Ω/□ or less, more preferably 10²Ω/□ or less in order to supply holes certainly to the organic layer 16.

<Second Electrode>

The second electrode 20 is constituted of an Al layer 18 and an Ag layer 19 disposed from the side of the organic layer 16.

—Al Layer—

The Al layer 18 constituting a part (lower layer) of the second electrode 20, has a thickness of from 0.1 nm to 10 nm. An Al layer 18 having such thickness may function as an electrode (cathode) supplying electrons to the organic layer 16, may also protect the organic layer 16 from the Ag layer 19 formed over the Al layer 18, and may have transparency with respect to the light emitted from the light emitting layer. Here, from the viewpoints of the electrical conductivity required of a part of the second electrode 20, protection of the organic layer, and light transparency, the thickness of the Al layer 18 is preferably from 0.5 nm to 5 nm, and more preferably from 1 nm to 3 nm.

—Ag Layer—

An Ag layer 19 is provided on the Al layer 18 as a part (upper layer) of the second electrode 20. The thickness of the Ag layer 19 is from 3 nm to 50 nm. An Ag layer 19 having such a thickness may have the electrical conductivity required of an electrode along with the Al electrode, as well as transparency with respect to the light emitted from the light emitting layer. From the viewpoints of the electrical conductivity required of a part of the second electrode 20, and light transparency, the thickness of the Ag layer 19 is preferably from 5 nm to 30 nm, and more preferably from 10 nm to 25 nm.

The overall thickness of the second electrode 20 is less than or equal to the sum of the upper limit of the Al layer 18 (10 nm) and the upper limit of the Ag layer 19 (50 nm), which is 60 nm or less. However, from the viewpoints of securing the electrical conductivity required of an electrode and transmitting the light emitted from the light emitting layer, the thickness is preferably from 10 nm to 50 nm, more preferably from 10 nm to 40 nm, and particularly preferably from 15 nm to 30 nm.

From the viewpoint that the Al layer 18 constituting the lower layer of the second electrode 20 mainly exhibits a function of protecting the organic layer 16 from the Ag layer 19, while the Ag layer 19 constituting the upper layer mainly exhibits electrical conductivity as an electrode, it is preferable that the thickness of the Al layer 18 be relatively smaller, and the thickness of the Ag layer 19 be relatively larger. Specifically, the ratio of the thickness of the Al layer 18 to the thickness of the Ag layer 19 (thickness of Al layer:thickness of Ag layer) is preferably in the range of 4:1 to 1:20, and more preferably in the range of 1:1 to 1:20.

In the case of producing an organic electroluminescent element 10 having a resonator structure, it is desirable to form the electrodes 14 and 20 so that the first electrode 14 has reflectivity and the second electrode 20 has reflectivity and transparency, with respect to the light emitted from the light emitting layer, and to adjust the optical path length that is determined from the effective refractive index of these two electrodes 14 and 20, and from the respective refractive indices and thicknesses of the electrodes 14 and 20, to an optimal value for obtaining a desired resonant wavelength. The calculation formulas that may be used in the case of having a resonator structure are described in, for example, JP-A Nos. 9-180883, 2004-127795, and the like, and it is desirable to form the respective layers of the organic electroluminescent element based on these calculation formulas.

Furthermore, in the case of forming a resonator structure, it is preferable to make the Ag layer 19 thicker than the Al layer 18, for the purpose of obtaining a balance between light reflectivity and light transparency of the second electrode 20 as a whole, in addition to the respective functions required of the Al layer 18 and the Ag layer 19 as described above. Specifically, the ratio of the thickness of the Al layer 18 to the thickness of the Ag layer 19 (thickness of Al layer:thickness of Ag layer) is more preferably in the range of 1:1 to 1:20, even more preferably in the range of 1:3 to 1:20, and particularly preferably in the range of 1:5 to 1:15.

There is no particular limitation in the method for forming the Al layer 18 and the Ag layer 19, which constitute the second electrode 20, and these layers can be formed according to any known method. For example, the layers may be formed sequentially according to a method appropriately selected from wet methods such as a printing method and a coating method; physical methods such as a vacuum deposition method, a sputtering method and an ion plating method; chemical methods such as a CVD method and a plasma CVD method; and the like, by taking account of the suitability of the method with each material (Al or Ag).

The second electrode 20 may be formed over the entire surface of the organic layer 16, or may be formed over a part of the organic layer 16. In the case of performing patterning after depositing an Al layer 18 and an Ag layer 19 sequentially to form the second electrode 20 on the organic layer 16, the patterning may be carried out by performing chemical etching using photolithography or the like, or may be carried out by performing physical etching using a laser or the like. The formation of the second electrode may also be carried out by superimposing a mask and performing vacuum deposition, sputtering or the like, or may be carried out according to a lift-off method or a printing method.

<Organic Layer>

The organic layer 16 is interposed between the first electrode (anode) 14 and the second electrode (cathode) 20, and is constituted to include at least a light emitting layer. The organic layer 16 between the electrodes 14 and 20 may adopt, for example, a layer constitution as shown below; however, the layer constitution is not to be limited to these constitutions, and may be appropriately determined in accordance with the purpose and the like.

Anode/light emitting layer/cathode

Anode/hole transport layer/light emitting layer/electron transport layer/cathode

Anode/hole transport layer/light emitting layer/block layer/electron transport layer/cathode

Anode/hole transport layer/light emitting layer/block layer/electron transport layer/electron injection layer/cathode

Anode/hole injection layer/hole transport layer/light emitting layer/block layer/electron transport layer/cathode

Anode/hole injection layer/hole transport layer/light emitting layer/block layer/electron transport layer/electron injection layer/cathode

Anode/hole transport layer/block layer/light emitting layer/electron transport layer/cathode

Anode/hole transport layer/block layer/light emitting layer/electron transport layer/electron injection layer/cathode

Anode/hole injection layer/hole transport layer/block layer/light emitting layer/electron transport layer/cathode

Anode/hole injection layer/hole transport layer/block layer/light emitting layer/electron transport layer/electron injection layer/cathode

—Light Emitting Layer—

The light emitting layer is a layer having a function of emitting light, when an electric field is applied, by receiving holes from the anode, the hole injection layer or the hole transport layer, receiving electrons from the cathode, the electron injection layer or the electron transport layer, and providing a site for the recombination of the holes and the electrons.

The light emitting layer may be formed of a light emitting material only or may be formed of a mixed layer of a host material and a light emitting material. The light emitting material may be a fluorescence material or phosphorescence material and may contain one or more dopants. The host material is preferably a charge transport material. The light emitting layer may contain one or more host materials which may be constituted, for example, of a mixture of an electron-transporting host material and a hole-transporting host material. The light emitting layer may contain a non-light emitting material not having an ability to transport charge.

The light emitting layer may be composed of one or more layers which may emit lights having luminescent colors different from one another.

Examples of the fluorescence material which may be used in the invention include benzoxazol derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, condensed aromatic compounds, perynone derivatives, oxadiazole derivatives, oxazine derivatives, aldazine derivatives, pyralidine derivatives, cyclopentadiene derivatives, bisstyrylanthracene derivatives, quinacridon derivatives, pyrrolopyridine derivatives, thiadiazolopyridine derivatives, cyclopentadiene derivatives, styrylamine derivatives, diketopyrrolopyrrole derivatives, aromatic dimethylidyne compounds, various metal complexes, typical examples of which include metal complexes of an 8-quinolinol derivative, and metal complexes of a pyrromethene derivative, polymeric compounds such as polythiophene, polyphenylene and polyphenylenevinylene, and organic silane derivatives.

Examples of the phosphorescence material which may be used in the invention include complexes each containing a transition metal atom or a lanthanoid atom.

The transition metal atom is not particularly limited, but preferably ruthenium, rhodium, palladium, tungsten, rhenium, osmium, iridium, or platinum, more preferably rhenium, iridium or platinum.

Examples of the lanthanoid atom include lanthanum, cerium, praseodymium, neodymium, samarium, europium, gadolinium, terbium, dysprosium, holmium, erbium, thulium, ytterbium, and lutetium. Of these lanthanoid atoms, neodymium, europium and gadolinium are preferred.

Examples of the ligand of the complexes include ligands described in G. Wilkinson et al., “Comprehensive Coordination Chemistry”, published by Pergamon Press Co. in 1987; H. Yersin, “Photochemistry and Photophysics of Coordination Compounds”, published by Springer-Verlag Co. in 1987; and Akio Yamamoto, “Organometallic Chemistry -Principles and Applications-”, published by Shokabo Publishing Co., Ltd. in 1982.

Preferred specific examples of the ligand include halogen ligands (preferably, a chlorine ligand), nitrogen-containing heterocyclic ligands (such as phenylpyridine, benzoquinoline, quinolinol, bipyridyl, and phenanthroline), diketone ligands (such as acetylacetone), carboxylic acid ligands (such as an acetic acid ligand), a carbon monoxide ligand, an isonitrile ligand, and a cyano ligand. More preferred are nitrogen-containing heterocyclic ligands. The above-mentioned complexes may each have a single transition metal atom in the compound thereof, or may each be a multi-nucleus complex, which has two or more transition metal atoms. The multi-nucleus complex may have different metal atoms together.

Among these, specific examples of the light emitting material include the phosphorescence emitting compounds described in patent documents such as, for example, U.S. Pat. No. 6,303,238 B1, U.S. Pat. No. 6,097,147, WO 00/57676, WO 00/70655, WO 01/08230, WO 01/39234 A2, WO 01/41512 A1, WO 02/02714 A2, WO 02/15645 A1, WO 02/44189 A1, JP-A Nos. 2001-247859, 2002-117978, 2002-225352, 2002-235076, and 2002-170684, EP 1,211,257, JP-A Nos. 2002-226495, 2002-234894, 2001-247859, 2001-298470, 2002-173674, 2002-203678, 2002-203679, 2004-357791, 2006-256999; and the like. Inter alia, particularly preferred light emitting materials are Ir complexes, Pt complexes and Re complexes, and among them, Ir complexes, Pt complexes and Re complexes containing at least one coordinate form selected from metal-carbon bonding, metal-nitrogen bonding, metal-oxygen bonding and metal-sulfur bonding, are preferable.

Among these, specific examples of the light emitting material include those shown below, but are not intended to be limited to these.

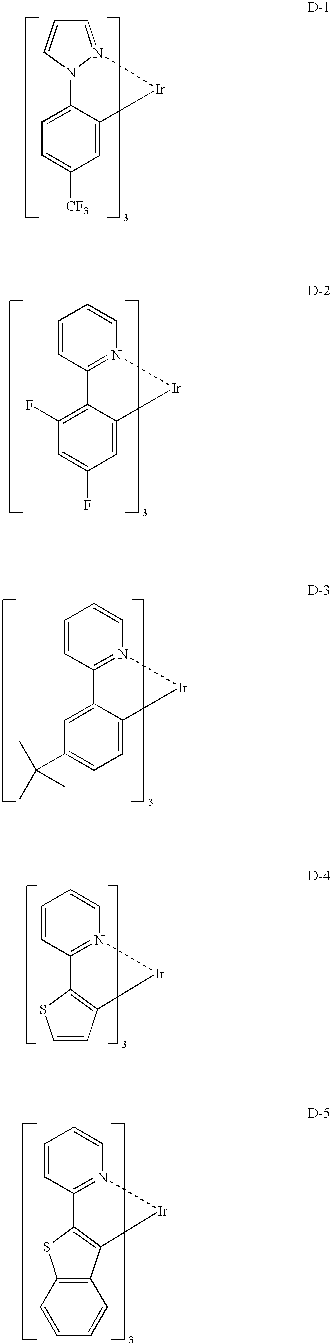

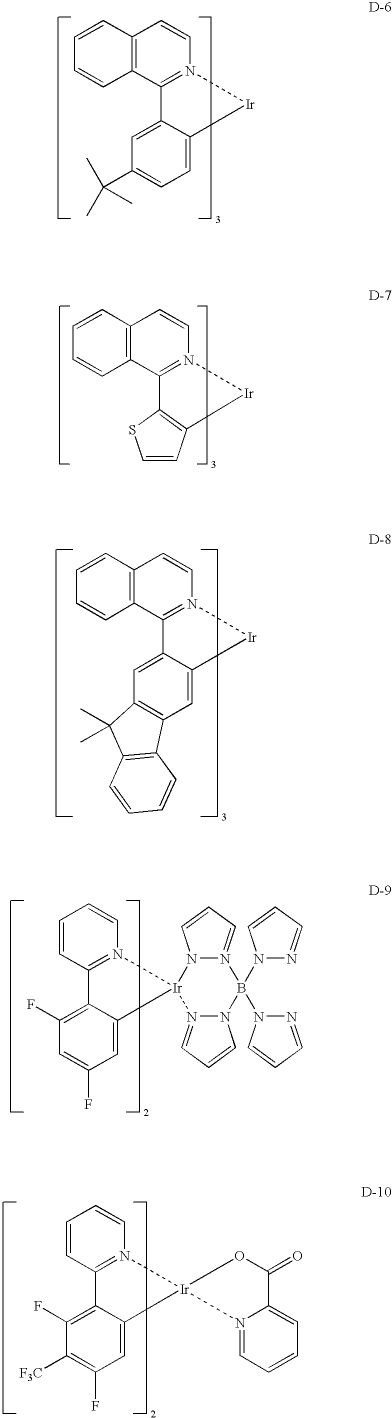

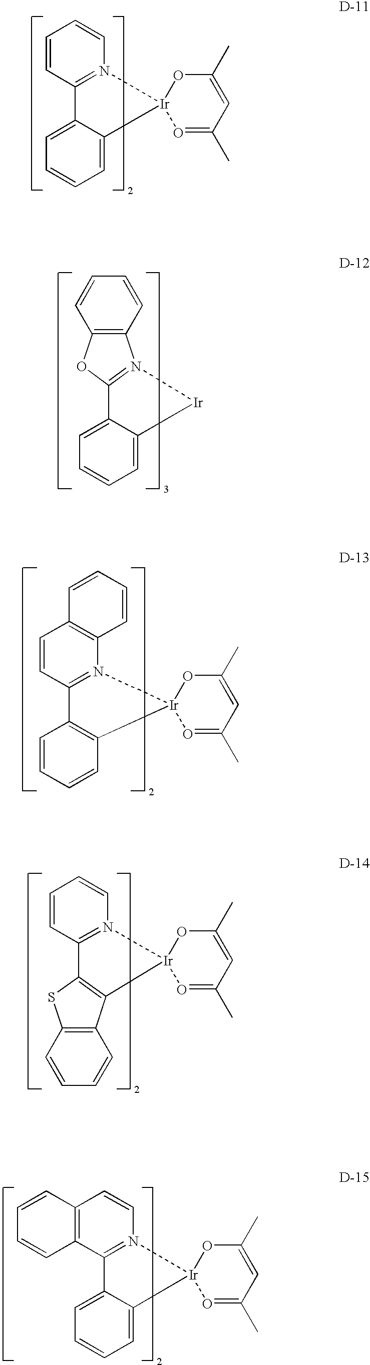

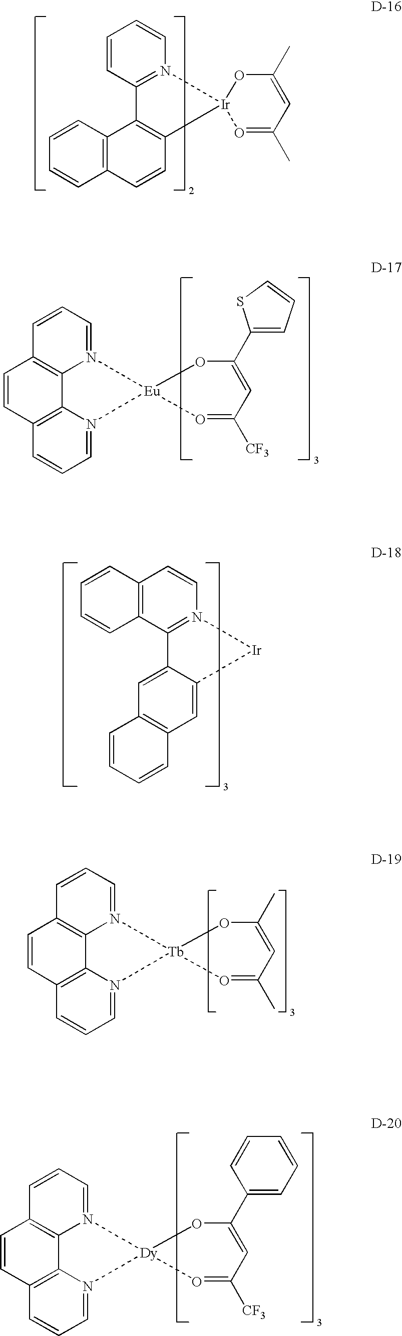

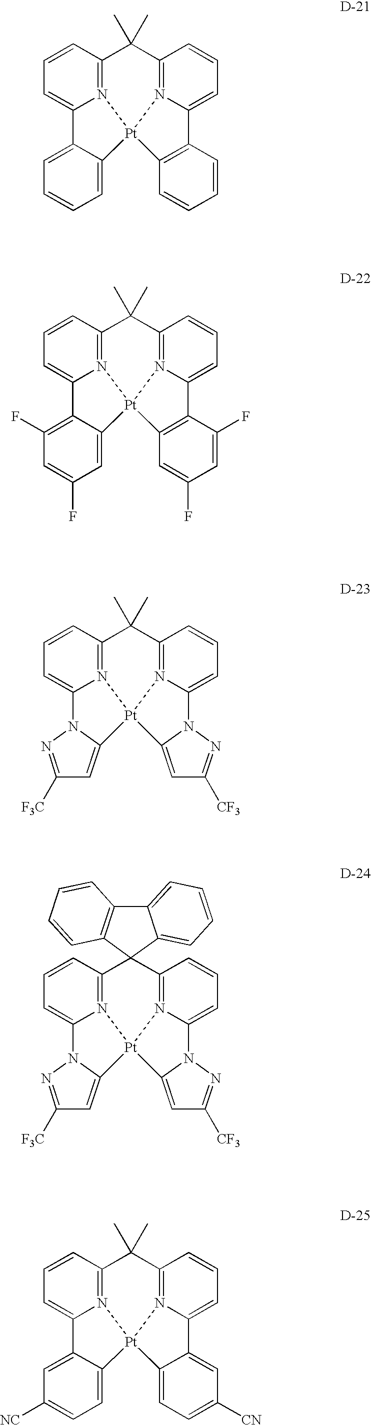

The phosphorescence material is contained in the light emitting layer preferably in a proportion of 0.1 to 40% by mass of the layer, more preferably in a proportion of 0.5 to 20% by mass thereof.

Specific examples of the host material contained in the light emitting layer include materials having a carbazole skeleton, materials having a diarylamine skeleton, materials having a pyridine skeleton, materials having a pyrazine skeleton, materials having a triazine skeleton, materials having an arylsilane skeleton, and materials exemplified in items “hole injection layer and hole transport layer”, and “electron injection layer and electron transport layer”, which will be described later.

The thickness of the light emitting layer is not particularly limited. Usually, the thickness is preferably from 1 to 500 nm, more preferably from 5 to 200 nm, even more preferably from 10 to 100 nm.

—Hole Injection Layer and Hole Transport Layer—

The hole injection layer and the hole transport layer are each layer having a function of receiving holes from the anode or the anode side and transporting the holes to the cathode side thereof. Specifically, the hole injection layer and the hole transport layer are each preferably a layer containing one or more selected from carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazane derivatives, aromatic tertiary amine compounds, styrylamine compounds, aromatic dimethylidene compounds, porphyrin compounds, organic silane derivatives, carbon, and various metal complexes, typical examples of which include Ir complexes each having phenylazole or phenylazine as a ligand.

The thickness of each of the hole injection layer and the hole transport layer is preferably 500 nm or less in order to make the driving voltage low.

The thickness of the hole transport layer is preferably from 1 to 500 nm, more preferably from 5 to 200 nm, even more preferably from 10 to 200 nm. The thickness of the hole injection layer is preferably from 0.1 to 200 nm, more preferably from 0.5 to 200 nm, even more preferably from 1 to 200 nm.

The hole injection layer and the hole transport layer may each have a monolayer structure made of one or more selected from the above-mentioned materials, or a multilayered structure composed of plural secondary layers which have the same composition or different compositions.

Specific compound examples of such a hole transport material include those shown below, but are not intended to be limited to these.

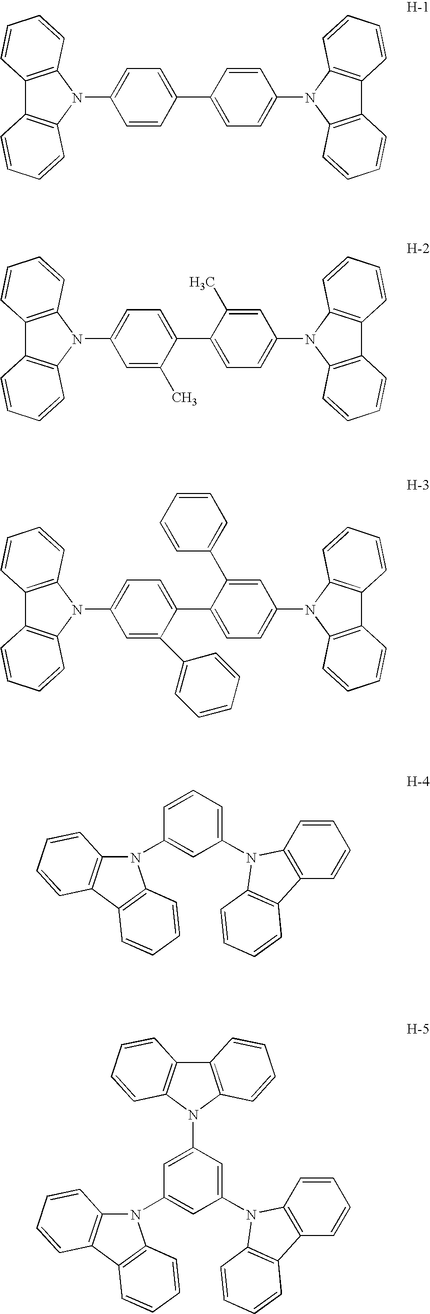

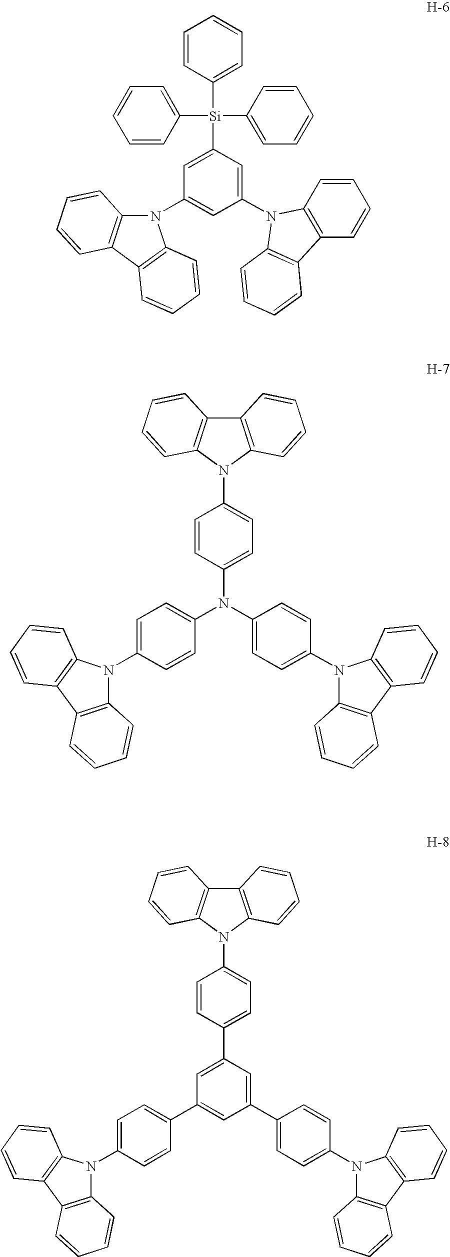

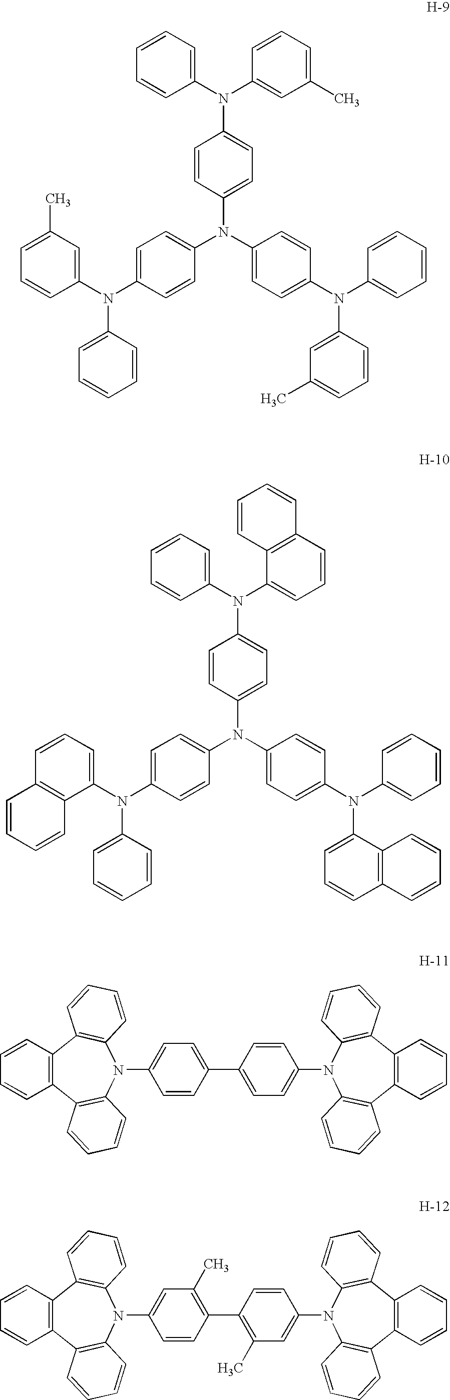

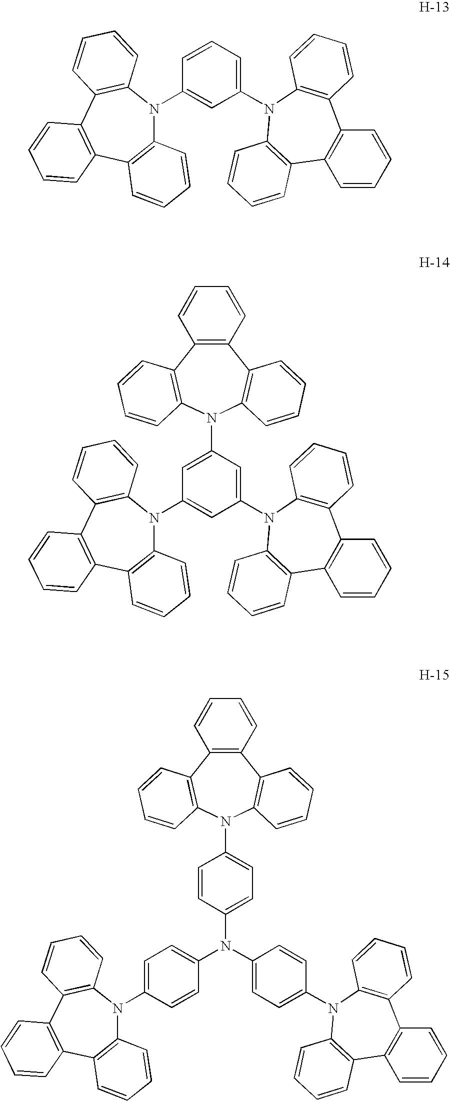

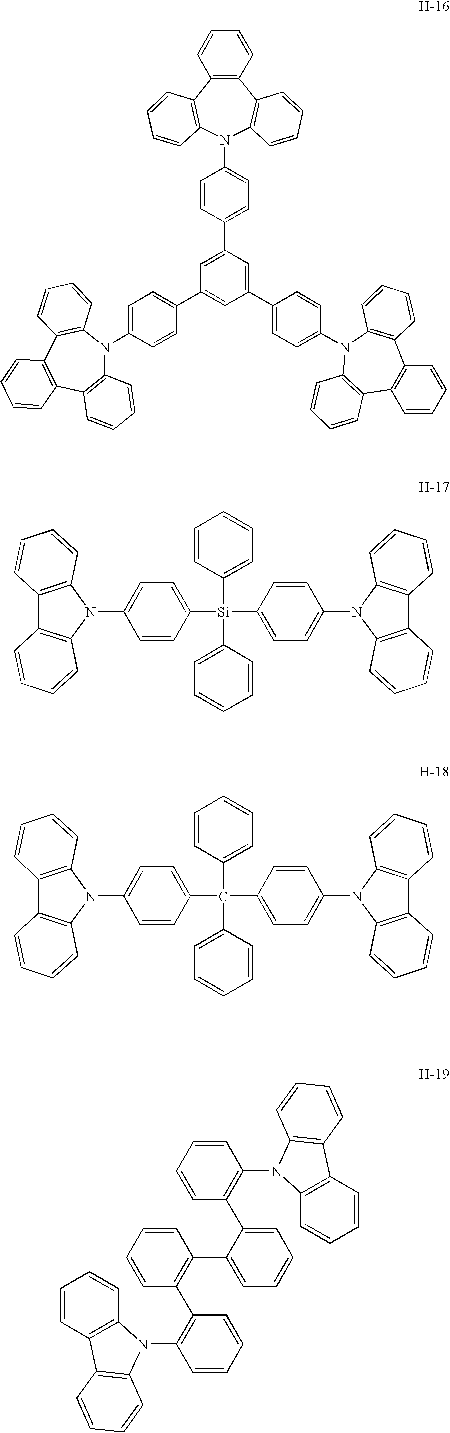

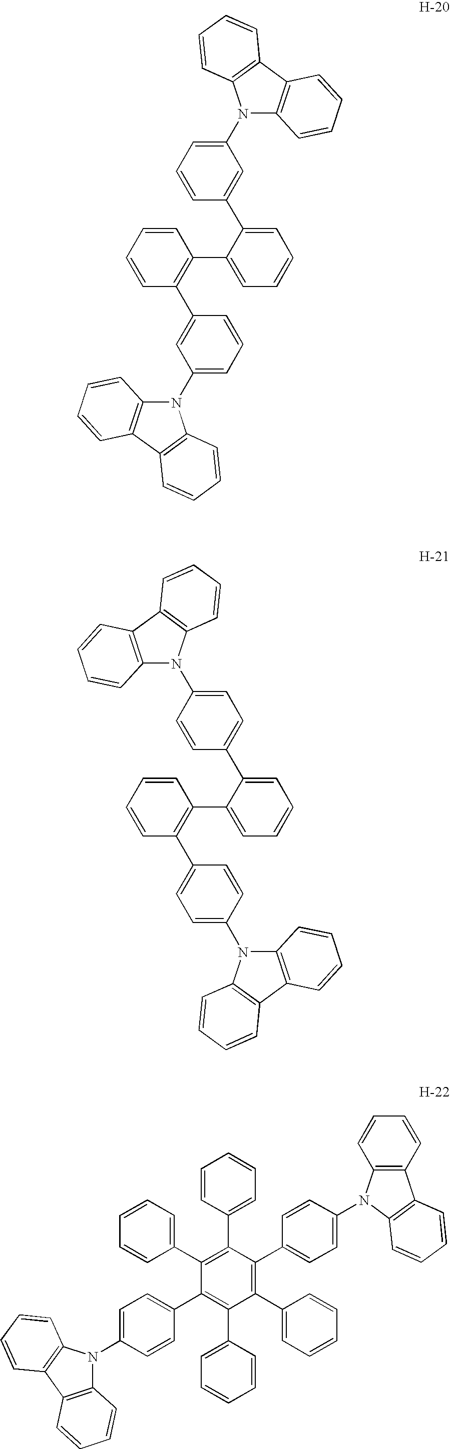

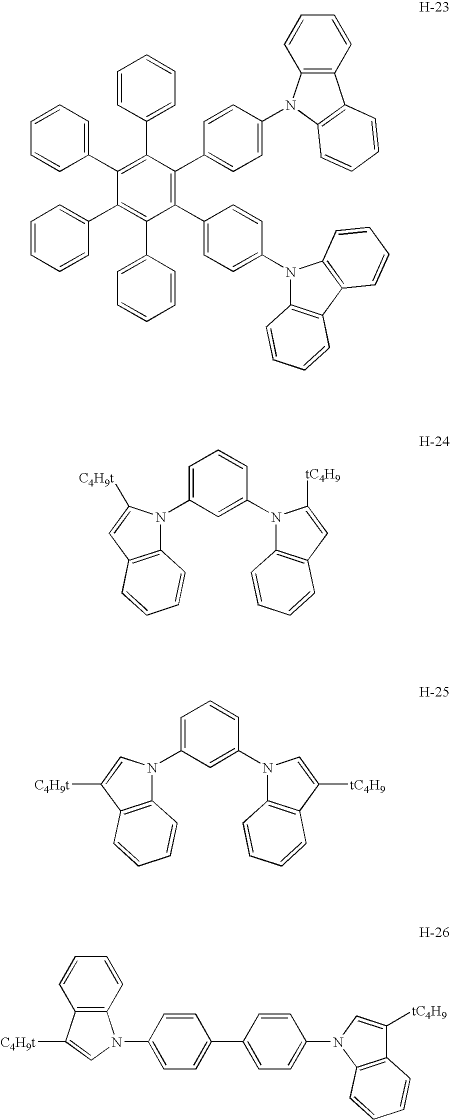

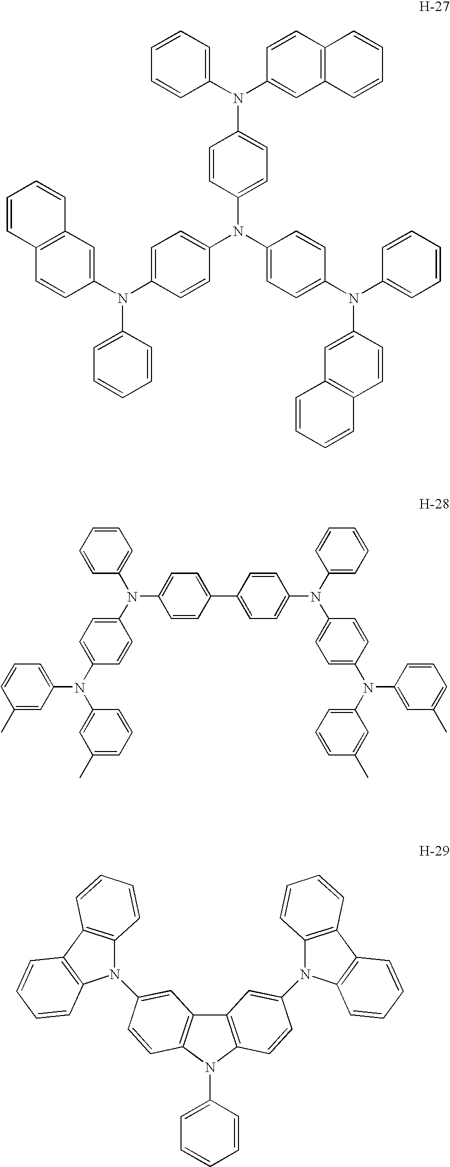

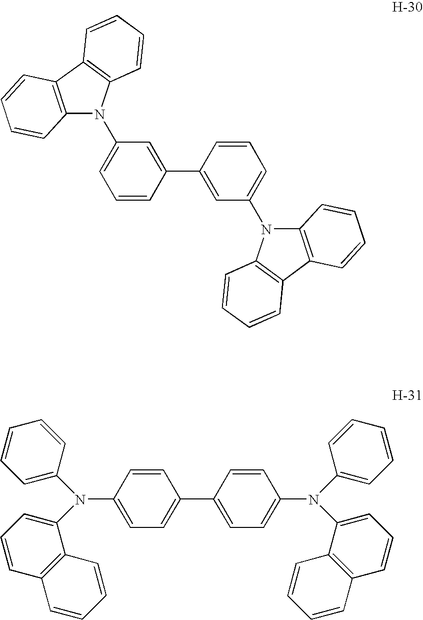

The hole inject layer and/or hole transport layer of the organic EL element of the invention may preferably contain an electron-accepting dopant (electron donor), from the viewpoints of voltage reduction and driving durability.

As for the electron donor to be introduced into the hole injection layer or the hole transport layer, inorganic compounds as well as organic compounds can all be used as long as they are electron-accepting and have a property of oxidizing an organic compound. Specific examples of the inorganic compounds that may be suitably used include halides such as ferric chloride, aluminum chloride, gallium chloride, indium chloride, and antimony pentachloride, and metal oxides such as molybdenum oxide, vanadium oxide and ruthenium oxide.

Examples of the organic compounds that may be suitably used include compounds having a nitro group, a halogen atom, a cyano group, a trifluoromethyl group or the like as a substituent, quinone compounds, acid anhydride compounds, fullerene, and the like.

Specific examples of the organic electron donor include hexacyanobutadiene, hexacyanobenzene, tetracyanoethylene, tetracyanoquinodimethane, tetrafluorotetracyanoquinodimethane, p-fluoranyl, p-chloranyl, p-bromanyl, p-benzoquinone, 2,6-dichlorobenzoquinone, 2,5-dichlorobenzoquinone, tetramethylbenzoquinone, 1,2,4,5-tetracyanobenzene, o-dicyanobenzene, p-dicyanobenzene, 1,4-dicyanotetrafluorobenzene, 2,3-dichloro-5,6-dicyanobenzoquinone, p-dinitrobenzene, m-dinitrobenzene, o-dinitrobenzene, p-cyanonitrobenzene, m-cyanonitrobenzene, o-cyanonitrobenzene, 1,4-naphthoquinone, 2,3-dichloronaphthoquinone, 1-nitronaphthalene, 2-nitronaphthalene, 1,3-dinitronaphthalene, 1,5-dinitronaphthalene, 9-cyanoanthracene, 9-nitroanthracene, 9,10-anthraquinone, 1,3,6,8-tetranitrocarbazole, 2,4,7-trinitro-9-fluorenone, 2,3,5,6-tetracyanopyridine, maleic anhydride, phthalic anhydride, fullerene C60, fullerene C70, and the like. In addition to these, the compounds described in JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, and the like may be suitably used.

These electron-accepting dopants may be used singly, or may be used as mixtures of two or more species.

—Electron Injection Layer and Electron Transport Layer—

The electron injection layer and the electron transport layer are each a layer having a function of receiving electrons from the cathode or the cathode side and transporting the electrons to the anode side. Specifically, the electron injection layer and the electron transport layer are each preferably a layer containing one or more selected from triazole derivatives, oxazole derivatives, oxadiazole derivatives, imidazole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyrazine derivatives, aromatic ring tetracarboxylic acid anhydrides such as naphthalene and perylene, phthalocyanine derivatives, various metal complexes, typical examples of which include metal complexes of an 8-quinolinol derivative, metal phthalocyanines, and metal complexes each having benzoxazole or benzothiazole as a ligand, organic silane derivatives or the like.

Examples of materials used in such an electron injection layer and an electron transport layer include those shown below, but are not intended to be limited to these.

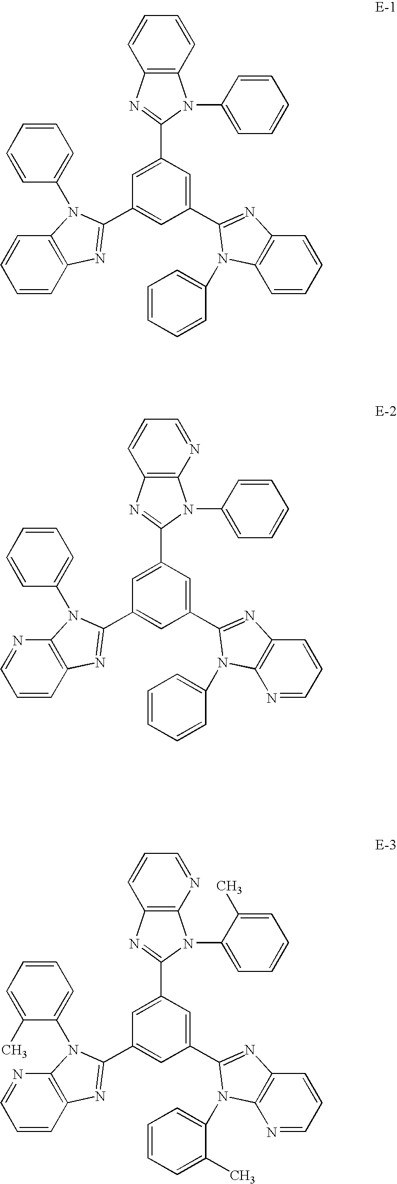

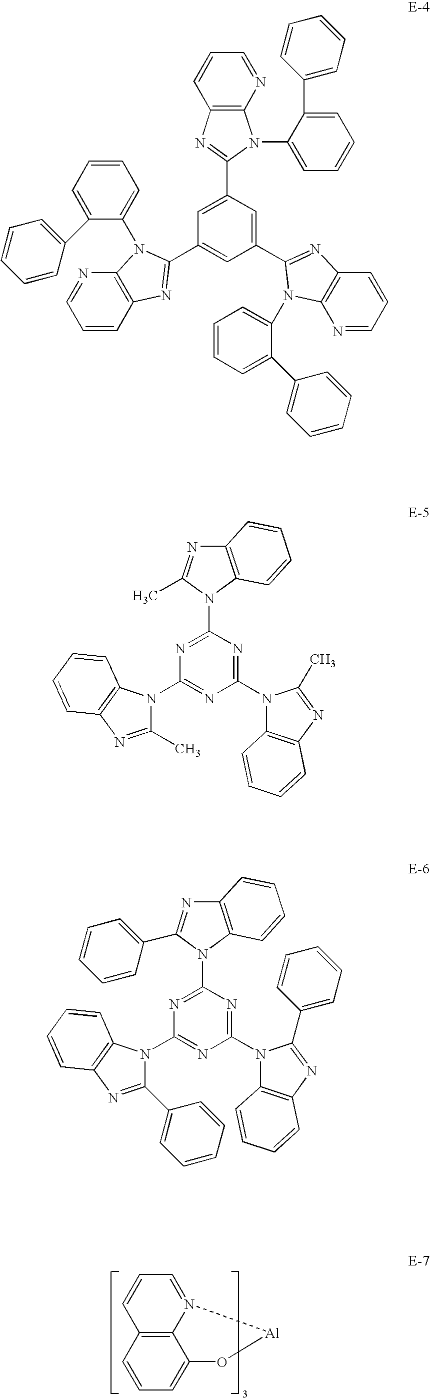

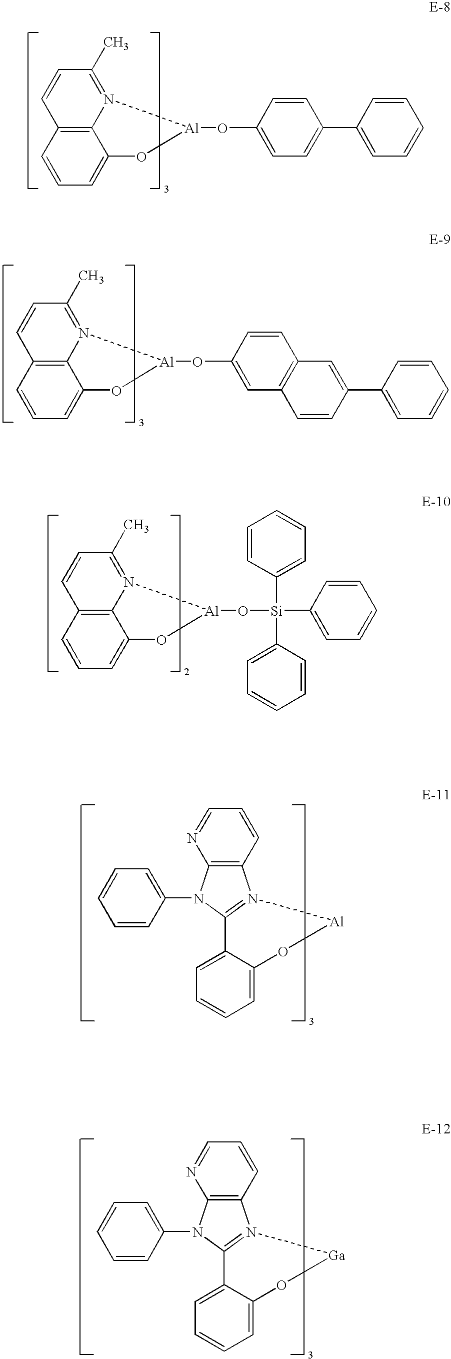

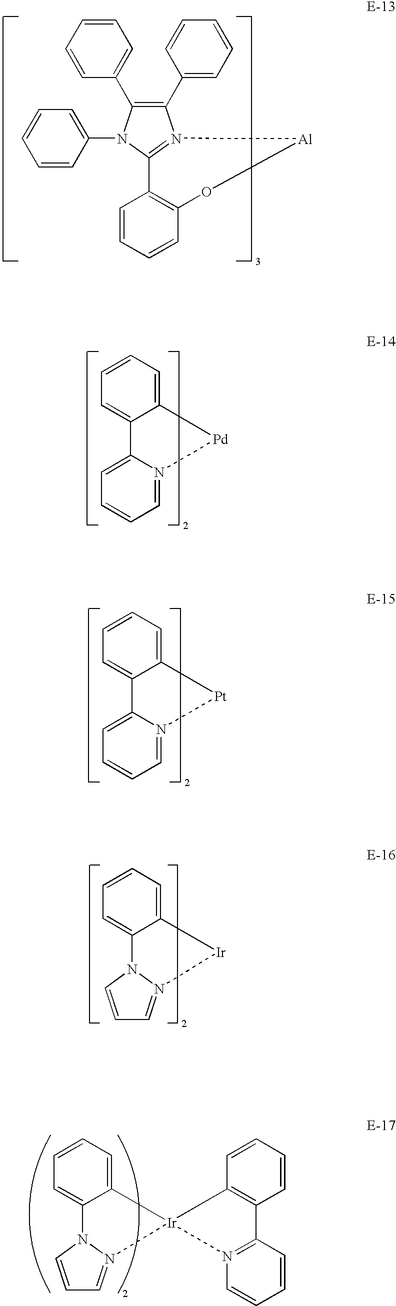

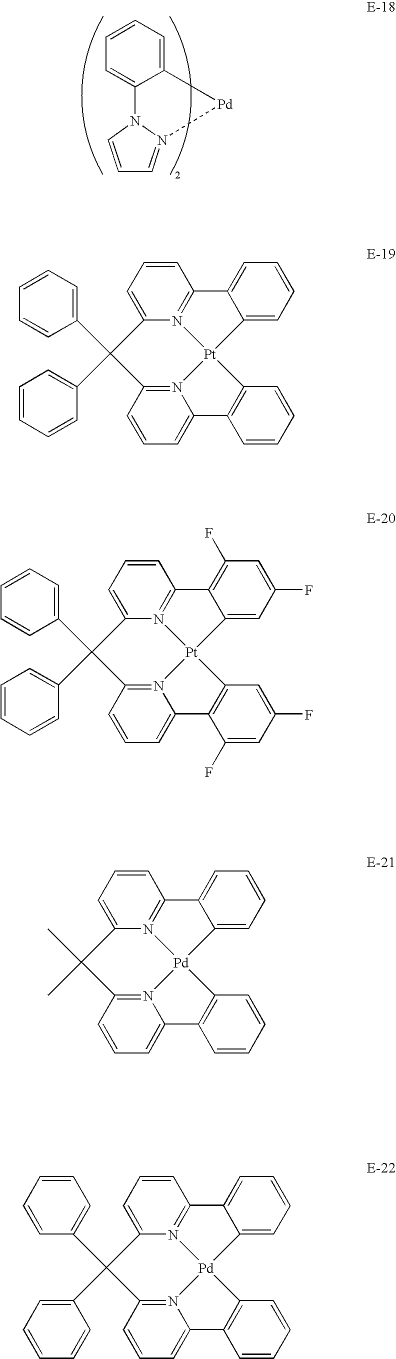

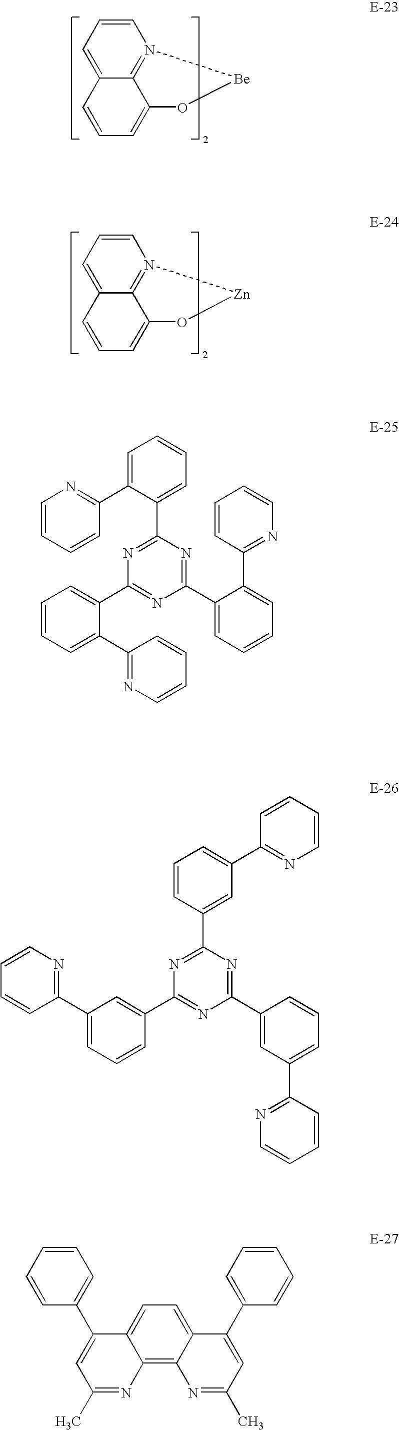

In regard to the electron injection layer and the electron transport layer according to the invention, it is preferable to incorporate the following electron-donating dopant (electron-donating material) into the electron injection layer or the electron transport layer, in order to enhance electron injectability from the second electrode.

The electron-donating material may be used if it is electron donatable and has a property of reducing an organic compound. Alkali metals such as lithium (Li), alkaline earth metals such as magnesium (Mg), transition metals including rare earth metals, and the like are suitably used.

Particularly, a metal having a work function of 4.2 eV or less can be suitably used, and specific example thereof include lithium (Li), sodium (Na), potassium (K), beryllium (Be), magnesium (Mg), calcium (Ca), strontium (Sr), barium (Ba), yttrium (Y), cesium (Cs), lanthanum (La), samarium (Sm), gadolinium (Gd), ytterbium (Yb), and the like.

Among these, alkali metals such as Li, Na, K and Cs are preferable, doping with Li or Cs is more preferable, and doping with Li is particularly preferable.

The amount of the alkali metal doped in the electron injection layer may vary depending on the type of the dopant, but from the viewpoint of enhancing electron injectability, the amount is preferably from 0.1% by mass to 99% by mass, more preferably from 1.0% by mass to 80% by mass, and particularly preferably from 2.0% by mass to 70% by mass, relative to the electron transporting material.

If the amount used is less than 0.1% by mass relative to the electron transport layer material, the effects of the invention are insufficiently manifested, which is not preferable. If the amount exceeds 99% by mass, the electron transporting ability is impaired, which is not preferable.

The thickness of each of the electron injection layer and the electron transport layer is preferably 500 nm or less in order to make the driving voltage low.

The thickness of the electron transport layer is preferably from 1 to 500 nm, more preferably from 5 to 200 nm, even more preferably from 10 to 100 nm. The thickness of the electron injection layer is preferably from 0.1 to 200 nm, more preferably from 0.2 to 100 nm, even more preferably from 0.5 to 50 nm.

The electron injection layer and the electron transport layer may each have a monolayer structure made of one or more selected from the above-mentioned materials, or a multilayered structure composed of plural secondary layers which have the same composition or different compositions.

—Hole Block Layer—

The hole block layer is a layer having a function of preventing holes transported from the anode side to the light emitting layer from going through to the cathode side. The hole block layer adjacent to the light emitting layer at the cathode side thereof may be formed.

The hole block layer may be made of an organic compound, and examples thereof include aluminum complexes such as BAlq, triazole derivatives, and phenanthroline derivatives such as BCP.

The thickness of the hole block layer is preferably from 1 to 500 nm, more preferably from 5 to 200 nm, even more preferably from 10 to 100 nm.

The hole block layer may have a monolayer structure made of one or more selected from the above-mentioned materials, or a multilayered structure composed of plural secondary layers which have the same composition or different compositions.

Each of the layers constituting the organic layer 16 may be formed by a method selected from dry film forming methods such as deposition methods and sputtering methods, transfer methods, printing methods, and the like, in accordance with the material. Each of the layers constituting the organic layer 16 may also be divided into plural secondary layers.

—AlLi Layer—

It is preferable to provide a layer formed from an alloy of Al and an alkali metal, particularly a layer of an alloy of Al and Li (AlLi layer), between the organic layer 16 and the second electrode 20. For example, when an electron transporting layer has been formed as the uppermost layer of the organic layer 16, the electron injectability from the second electrode 20 to the organic layer 16 is enhanced if an AlLi layer is provided between the electron transport layer and the second electrode 20 (Al layer 18). Furthermore, when an electron injection layer has been formed as the uppermost layer of the organic layer 16, the electron injectability may be further enhanced by providing an AlLi layer between the electron injection layer and the second electrode 20 (Al layer 18).

The thickness of the AlLi layer is preferably 3 nm or less, more preferably from 0.1 nm to 2 nm, and particularly preferably from 0.3 nm to 1 nm, from the viewpoint of enhancing electron injectability as well as preventing a decrease in light transparency.

The AlLi layer can be formed by, for example, a vacuum deposition method, a sputtering method, an ion plating method, or the like.

<Sealing Substrate and the Like>

After forming the organic electroluminescent element 10 on a supporting substrate 12, the element is sealed to suppress deterioration caused by the moisture or oxygen in the atmosphere.

As for the sealing substrate 22, a substrate having light transparency and also having high barrier properties against oxygen or moisture is used. Preferably, a glass substrate or a resin film provided with a barrier layer may be used. The thickness of the sealing substrate is preferably from 0.05 to 2 mm, from the viewpoints of light transparency, strength, weight reduction and the like.

As a sealing substrate 22 made from a resin film, the same material as that used in the supporting substrate 12, such as PET, PEN or PES, may be used. The thickness of the barrier layer may be determined in accordance with the material or required barrier properties, but the thickness is usually from 100 nm to 5 μm, and more preferably from 1 μm to 5 μm.

As a sealing member that fixes the sealing substrate 22 onto the supporting substrate 12 and also prevents air penetration, an adhesive is preferable, and a photocurable adhesive or a thermosetting adhesive such as an epoxy resin may be used. For example, a thermosetting adhesive sheet can be used.

At the time of sealing, the space between the sealing substrate 22 and the supporting substrate 12 is filled with a gaseous or liquid inert fluid. Examples of inert gas include argon, nitrogen, and the like. Examples of inert liquid include paraffins, liquid paraffins, fluorine-containing solvents such as perfluoroalkanes, perfluoroamines, and perfluoroethers, chlorine-containing solvents, and silicone oils.

When external wires (not shown) are connected respectively to the upper and lower electrodes 20 and 14, and a direct current (may include alternating current components, if necessary) voltage (usually from 2 volts to 15 volts), or a direct electric current is applied, the organic layer 16 in the region interposed between the two electrodes can be made to emit light. Furthermore, in regard to the method of driving, those driving methods described in JP-A Nos. 2-148687, 6-301355, 5-29080, 7-134558, 8-234685, and 8-241047, Japanese Patent 2,784,615, U.S. Pat. No. 5,828,429, U.S. Pat. No. 6,023,308, and the like can be applied.

After going through the processes as described above, a top emission type light emitting device 24 equipped with the organic electroluminescent element 10 according to the invention is produced.

In this device 24, light can be extracted from the side of the electrode on the organic layer. Thus, for example, as compared with the case of forming only an Ag layer as the second electrode (upper electrode), a short circuit caused by the formation of the second electrode hardly occurs, and the device has high electron injectability into the organic layer and is driven at a low voltage, while a voltage increase resulting from the use of the element can be suppressed.

A preferred aspect of the organic electroluminescent element according to the invention is as follows.

The ratio of the thickness of the Al layer to the thickness of the Ag layer is in the range of 1:1 to 1:20.

A resonator structure is formed as a result of the first electrode having reflectivity and the second electrode having reflectivity and transparency, with respect to the light emitted from the organic layer.

The organic layer includes an electron injection layer doped with an alkali metal.

The alkali metal is Li or Cs.

There is a layer of an alloy of Al and Li between the organic layer and the second electrode.

The thickness of the layer of an alloy of Al and Li is 3 nm or less.

### EXAMPLES

### Example 1-1

An Al electrode (anode) was formed as a first electrode on a supporting substrate (material: glass, 20 mm×20 mm) to a thickness of 100 nm and in a striped pattern with a width of 2 mm. The supporting substrate having the Al electrode formed thereon was installed in a substrate holder inside a vacuum deposition apparatus, with a mask exposing the area for forming an organic layer (aperture: 5 mm×5 mm). Subsequently, the inside of the apparatus was evacuated to obtain a degree of vacuum of 5×10⁻⁵ Pa. On the anode, co-deposition of 2-TNATA (the compound of H-27) and F4-TCNQ shown below was performed to form a hole injection layer having a thickness of 160 nm, such that the amount of F4-TCNQ with respect to 2-TNATA was 1.0% by mass. Subsequently, a hole transport layer was formed using NPD (the compound of H-31) to a thickness of 10 nm, and then using the compound of H-29 in succession. After forming the hole transport layer, co-deposition of the compound of H-30 and the compound of D-25 was performed to form a light emitting layer having a thickness of 30 nm, such that the amount of the compound D-25 with respect to the compound H-30 was 15% by mass. Subsequently, an electron transport layer was formed using BAlq (the compound of E-8) to a thickness of 40 nm.

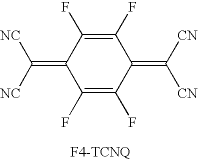

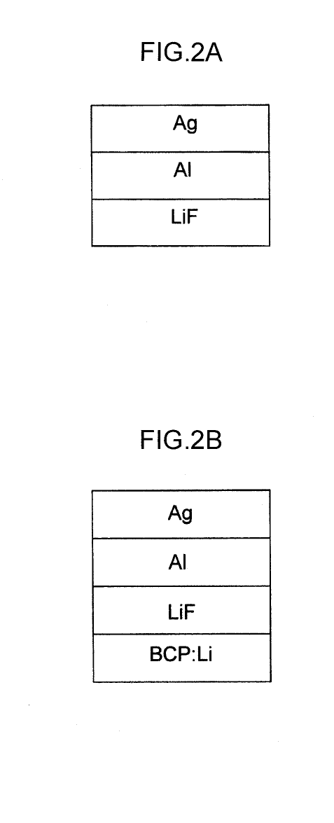

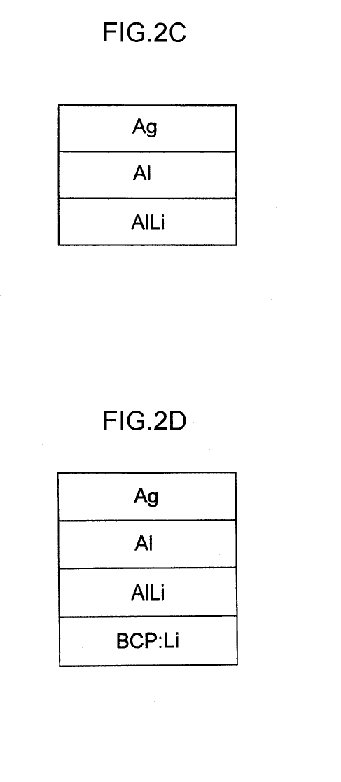

An LiF layer (thickness: 1 nm), an Al layer (thickness: 1.5 nm), and an Ag layer (thickness: 20 nm) were sequentially formed by vapor deposition on the electron transport layer, similarly to the layer constitution shown in FIG. 2A. Patterning was performed using a mask to give a striped pattern with a width of 2 mm, such that the second electrode (cathode) composed of the Al layer and the Ag layer was perpendicular to the first electrode (Al electrode) on the substrate. Thereby, pixels of the organic electroluminescent element measuring 2 mm×2 mm were produced.

The organic electroluminescent element produced as described above was transferred into a globe box filled with a nitrogen atmosphere, and a sealing substrate was attached. A glass substrate measuring 10 mm×10 mm and having a thickness of 1 mm was used as the sealing substrate, and a desiccant was attached thereto. A photosensitive epoxy resin having a glass spacer (diameter: 300 μm) dispersed therein was applied around the pixels on the supporting substrate of the organic electroluminescent element, and then the sealing substrate was pressed thereon such that the surface provided with the desiccant faced toward the organic electroluminescent element. The epoxy resin was cured using a UV lamp, and thus an organic electroluminescent element was obtained.

### Example 1-2

An organic electroluminescent element was produced in the same manner as in Example 1-1, except that the thickness of the Al layer used in Example 1-1 was changed to 2 nm.

### Example 1-3

An organic electroluminescent element was produced in the same manner as in Example 1-1, except that the thickness of the Ag layer used in Example 1-2 was changed to 25 nm.

### Example 1-4

An organic electroluminescent element was produced in the same manner as in Example 1-1, except that CBP (the compound of H-1) was used instead of the compound of H-30 used in Example 1-1.

### Example 1-5

Pixels of organic electroluminescent element was produced in the same manner as in Example 1-1, except that mCP (the compound of H-4) was used instead of the compound of H-30 used in Example 1-1.

### Example 2

Layers including from the Al electrode to the light emitting layer were formed on a glass substrate in the same layer constitution as that used in Example 1, and an electron transport layer of BAlq was formed to a thickness of 10 nm. Subsequently, a BCP:Li layer (thickness: 30 nm) of BCP doped with 1% Li, an LiF layer (thickness: 1 nm), an Al layer (thickness: 1.5 nm), and an Ag layer (thickness: 20 nm) were sequentially formed by vapor deposition on the electron transport layer, in the same layer constitution as shown in FIG. 2B. Patterning was performed using a mask to give a striped pattern with a width of 2 mm, such that the second electrode (cathode) composed of the Al layer and the Ag layer was perpendicular to the first electrode (Al electrode) on the substrate. Subsequently, sealing was carried out in the same manner as in Example 1, and thus an organic electroluminescent device was obtained.

### Example 3

Layers including from the Al electrode to the electron transport layer were formed on a glass substrate in the same layer constitution as that used in Example 1. Subsequently, an AlLi layer (thickness: 3 nm), an Al layer (thickness: 1.5 nm), and an Ag layer (thickness: 20 nm) were sequentially formed by vapor deposition on the electron transport layer, in the same layer constitution as shown in FIG. 2C. Patterning was performed using a mask to give a striped pattern with a width of 2 mm, such that the second electrode (cathode) composed of the Al layer and the Ag layer was perpendicular to the first electrode (Al electrode) on the substrate. Subsequently, sealing was carried out in the same manner as in Example 1, and thus an organic electroluminescent device was obtained.

### Example 4

Layers including from the Al electrode to the electron transport layer were formed on a glass substrate in the same layer constitution as that used in Example 2. Subsequently, a BCP:Li layer (thickness: 30 nm), an AlLi layer (thickness: 3 nm), an Al layer (thickness: 1.5 nm), and an Ag layer (thickness: 20 nm) were sequentially formed by vapor deposition on the electron transport layer, in the same layer constitution as shown in FIG. 2D. Patterning was performed using a mask to give a striped pattern with a width of 2 mm, such that the second electrode (cathode) composed of the Al layer and the Ag layer was perpendicular to the first electrode (Al electrode) on the substrate. Subsequently, sealing was carried out in the same manner as in Example 1, and thus an organic electroluminescent device was obtained.

### Comparative Example 1

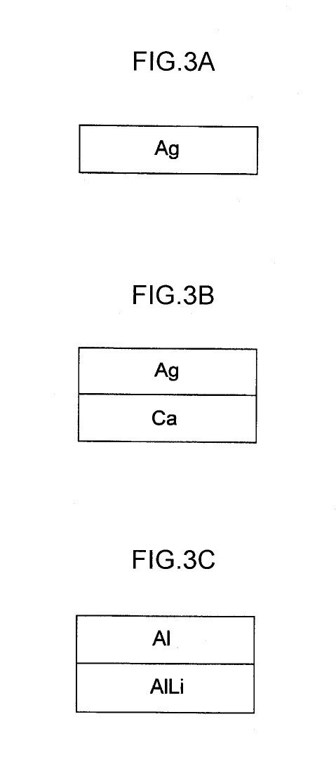

Layers including from the Al electrode to the electron transport layer were formed on a glass substrate in the same layer constitution as that used in Example 1. Subsequently, an Ag layer (thickness: 20 nm) was formed by vapor deposition as a cathode on the electron transport layer, as shown in FIG. 3A. Patterning was performed using a mask to give a striped pattern with a width of 2 mm. Subsequently, sealing was carried out in the same manner as in Example 1, and thus an organic electroluminescent device was obtained.

### Comparative Example 2

Layers including from the Al electrode to the electron transport layer were formed on a glass substrate in the same layer constitution as that used in Example 1. Subsequently, a Ca layer (thickness: 1.5 nm) and an Ag layer (thickness: 20 nm) were sequentially formed by vapor deposition as a cathode on the electron transport layer, in the same layer constitution as shown in FIG. 3B. Patterning was performed using a mask to give a striped pattern with a width of 2 mm, such that the cathode composed of the Ca layer and the Ag layer was perpendicular to the anode (Al electrode) on the substrate. Subsequently, sealing was carried out in the same manner as in Example 1, and thus an organic electroluminescent device was obtained.

### Comparative Example 3

Layers including from the Al electrode to the electron transport layer were formed on a glass substrate in the same layer constitution as that used in Example 1. Subsequently, an AlLi layer (thickness: 3 nm) and an Al layer (thickness: 20 nm) were sequentially formed by vapor deposition on the electron transport layer, in the same layer constitution as shown in FIG. 3C. Patterning was performed using a mask to give a striped pattern with a width of 2 mm, such that the Al layer serving as a cathode was perpendicular to the anode (Al electrode) on the substrate. Subsequently, sealing was carried out in the same manner as in Example 1, and thus an organic electroluminescent device was obtained.

—Evaluation of Organic Electroluminescent Devices—

The lines (terminals) taken out respectively from the anode and the cathode of a organic electroluminescent device produced as above were connected to a power supply through external wirings. The voltage needed to emit light at a luminance of 100 cd/m² was designated as a driving voltage, and the voltage needed to emit light at a luminance of 1000 cd/m² was designated as V₁. Driving of the device was initiated at a current for emitting light at a luminance of 1000 cd/m² and then, while maintaining the current, the voltage at the time when the luminance became 500 cd/m² was designated as V₂. The values of V₂ in Table 1 are shown with respect to values of V₁ taken as 100%.

TABLE 1

| | Constitution over | Occurrence of | | Rate of voltage increase at the time |
|---|---|---|---|---|
| | electron transport layer | short circuit | Driving voltage | of luminance reduction by half (V₂) |
| Example 1-1 | LiF/Al/Ag | None | 5.2 V | 113% |
| Example 1-2 | LiF/Al/Ag | None | 5.1 V | 116% |
| Example 1-3 | LiF/Al/Ag | None | 5.2 V | 110% |
| Example 1-4 | LiF/Al/Ag | None | 5.2 V | 115% |
| Example 1-5 | LiF/Al/Ag | None | 5.3 V | 115% |
| Example 2 | BCP: Li/LiF/Al/Ag | None | 3.8 V | 109% |
| Example 3 | AlLi/Al/Ag | None | 5.1 V | 111% |
| Example 4 | BCP: Li/AlLi/Al/Ag | None | 3.6 V | 108% |
| Comparative Example 1 | Ag | Occurs | — | — |
| Comparative Example 2 | Ca/Ag | Partially occurs | 5.4 V | 140% |
| Comparative Example 3 | AlLi/Al | None | 5.5 V | 131% |

The organic electroluminescent devices of Examples 1 to 4 do not cause a short circuit, and have a smaller rate of voltage increase by driving while maintaining the driving voltage almost equal or lower, compared with the organic electroluminescent devices of Comparative Examples 1 to 3.

When Ir(ppy)₃ is used at a concentration of 5%, as a light emitting material instead of D-25, the same results may be obtained.

Thus, the invention has been explained so far, but the invention is not intended to be limited to the exemplary embodiment and Examples.

For example, the organic electroluminescent element according to the invention may be used as a light source of an image forming apparatus or the like, and may also be used as a display device by forming pixels by patterning the light emitting layer to RGB.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. An organic electroluminescent element comprising a first electrode, an organic layer including at least a light emitting layer, and a second electrode, disposed in this order, wherein the second electrode comprises, starting from the side of the organic layer, an aluminum (Al) layer having a thickness of 0.1 nm to 10 nm and a silver (Ag) layer having a thickness of 3 nm to 50 nm.

2. The organic electroluminescent element of claim 1, wherein the thickness of the Al layer is from 1 nm to 3 nm.

3. The organic electroluminescent element of claim 1, wherein the thickness of the Ag layer is from 10 nm to 25 nm.

4. The organic electroluminescent element of claim 1, wherein the thickness of the second electrode is from 15 nm to 30 nm.

5. The organic electroluminescent element of claim 1, wherein a ratio of the thickness of the Al layer to the thickness of the Ag layer is in the range of 1:1 to 1:20.

6. The organic electroluminescent element of claim 1, wherein a ratio of the thickness of the Al layer to the thickness of the Ag layer is in the range of 1:5 to 1:15.

7. The organic electroluminescent element of claim 1, wherein a resonator structure is formed as a result of the first electrode having reflectivity and the second electrode having reflectivity and transparency, with respect to light emitted from the organic layer.

8. The organic electroluminescent element of claim 1, wherein the organic layer comprises an electron injection layer doped with an alkali metal.

9. The organic electroluminescent element of claim 8, wherein the alkali metal is lithium (Li) or cesium (Cs).

10. The organic electroluminescent element of claim 1, further comprising a layer of an alloy of Al and Li between the organic layer and the second electrode.

11. The organic electroluminescent element of claim 10, wherein the thickness of the layer of an alloy of Al and Li is 3 nm or less.
